(19) United States
(12) Patent Application Publication
(10) Pub. No.: US 2026/0157123 A1
(43) Pub. Date: Jun. 4, 2026

(54) RESISTIVE RANDOM-ACCESS MEMORY DEVICE AND METHODS OF FORMING THEREOF

(71) Applicants: International Business Machines Corporation, Armonk, NY (US); Tokyo Electron Limited, Tokyo (JP)

(72) Inventors: Steven Consiglio, Albany, NY (US); Kenichi Imakita, Albany, NY (US); Takaaki Tsunomura, Tokyo (JP); Paul Jamison, Hopewell Junction, NY (US); Takashi Ando, Yorktown Heights, NY (US); Kevin Brew, Yorktown Heights, NY (US)

(21) Appl. No.: 18/968,986

(22) Filed: Dec. 4, 2024

(51) Int. Cl. H10N 70/00; G11C 13/00; H10B 63/00; H10N 70/20

(52) U.S. Cl. CPC H10N 70/8833; G11C 13/0007; H10B 63/30; H10N 70/023; H10N 70/026; H10N 70/041; H10N 70/063; H10N 70/24; H10N 70/841; G11C 2213/71

(57) ABSTRACT

A method is provided for forming a resistive memory. The method includes forming a first metal line disposed over a substrate, wherein the first metal line is oriented along a first direction. A patterned stack is then formed, including a first electrode disposed over the first metal line and a first metal oxide layer disposed over the first electrode. The first metal oxide layer is then exposed to a nitriding surface treatment process. Subsequently, a first oxygen reservoir layer is disposed over the first metal oxide layer, and a second electrode is disposed over the first oxygen reservoir layer. Finally, a second metal line is formed over the second electrode, oriented along a second direction orthogonal to the first direction.

### TECHNICAL FIELD

This application relates generally to electronic devices, and, in particular embodiments, to resistive random-access memory (RRAM) device and methods for manufacturing and operating the same.

### BACKGROUND

One of the most promising types of resistive random-access memory (RRAM) is filamentary switching metal oxide-based RRAM, which leverages oxygen vacancies. In this type of RRAM, the switching mechanism is based on the formation and rupture of conducting filaments composed of oxygen vacancies within a resistive switching layer, typically made of metal oxides. When a forward voltage is applied, these filaments form, resulting in a low-resistance state. Conversely, applying a reverse voltage causes the filaments to rupture, returning the device to a high-resistance state.

The advantage of filamentary switching in metal oxide-based RRAM is particularly notable in analog computing applications. Analog switching allows for more efficient and faster processing of data compared to digital switching. This is because analog computing can process a range of values rather than just binary states, making it highly suitable for applications such as neuromorphic computing and artificial intelligence. The control of oxygen vacancy mobility is therefore crucial for controlling analog switching behavior and lower oxygen vacancy mobility may provide a benefit of a larger range of variable states.

To further enhance the performance of metal oxide-based RRAM devices, the use of an oxygen reservoir layer in conjunction with the resistive switching layer has been introduced. The oxygen reservoir layer helps to stabilize the concentration of oxygen vacancies, thereby improving the reliability and endurance of the device.

### SUMMARY

In accordance with one aspect of the present invention, a resistive memory is provided comprising a first metal line oriented along a first direction, a first electrode coupled to and disposed over the first metal line, a second electrode disposed over the first electrode, a first metal oxide layer disposed between the first and second electrodes, and a first oxygen reservoir layer disposed over the first metal oxide layer. An outer surface of the first metal oxide layer facing the first oxygen reservoir layer comprises nitrogen. The resistive memory further includes a second metal line coupled to and oriented along a second direction over the second electrode. The first and second electrodes, the first oxygen reservoir layer, and the first metal oxide layer form part of a resistive memory device.

In accordance with another aspect of the present invention, a method of forming a resistive memory is provided comprising forming a first metal line disposed over a substrate and oriented along a first direction, forming a patterned stack comprising a first electrode disposed over the first metal line and a first metal oxide layer disposed over the first electrode, exposing the first metal oxide layer to a nitriding surface treatment process, forming a first oxygen reservoir layer over the first metal oxide layer, forming a second electrode over the first oxygen reservoir layer, and forming a second metal line over the second electrode and oriented along a second direction orthogonal to the first direction.

In accordance with yet another aspect of the present invention, a method of forming a resistive memory is provided comprising forming a first metal line disposed over a substrate and oriented along a first direction, forming a patterned stack comprising a first electrode disposed over the first metal line, forming a first oxygen reservoir layer disposed over the first electrode, exposing the first oxygen reservoir layer to a nitriding surface treatment process, forming a first metal oxide layer over the first oxygen reservoir layer, forming a second electrode over the first metal oxide layer, and forming a second metal line over the second electrode and oriented along a second direction orthogonal to the first direction.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A and FIG. 1B illustrate a three-dimensional view of a resistive memory array and a cross-sectional view of a resistive memory, in accordance with an embodiment;

FIGS. 2A-2C illustrate the responses of resistive memory device to external electrical signal inputs, in accordance with an embodiment;

FIG. 3 illustrates a cross-sectional view of a resistive memory, wherein the resistive memory device comprises a variation in layer configuration, in accordance with an embodiment;

FIG. 4 illustrates a cross-sectional view of a resistive memory, wherein the resistive memory device comprises another variation in layer configuration, in accordance with an embodiment;

FIG. 5 illustrates a cross-sectional view of a resistive memory, wherein the resistive memory device comprises a third variation in layer configuration, in accordance with an embodiment;

FIGS. 6A-6J illustrate cross-sectional views of the formation of a resistive memory, in accordance with an embodiment;

FIG. 7A-7D illustrate top-down views of the formation of a resistive memory, in accordance with an embodiment;

FIG. 8 illustrates a process chamber for nitriding surface treatment process, in accordance with an embodiment;

### DETAILED DESCRIPTION OF ILLUSTRATIVE EMBODIMENTS

This disclosure relates to resistive random-access memory (RRAM) devices incorporating a nitriding treatment to control oxygen vacancy mobility within the stacking layers. Advantageously, such treatment may be optimized for analog computing applications. The accumulation of electrically conductive oxygen vacancies facilitates the formation of an electrically conducting filament within the resistive switching layer of a resistive memory device. Upon the formation of this oxygen vacancy conducting filament, electron mobility increases along the filament, thereby reducing the resistance of the resistive switching layer. By precisely modulating applied voltage values, the concentration of oxygen vacancies in the resistive switching layer may be continuously adjusted, thus altering the quantity and width of oxygen vacancy filaments. Consequently, the memory device resistance and corresponding output current continuously changes which may enable various applications in analog computing.

The nitriding treatment may introduce nitrogen atoms into the resistive switching layer or the oxygen reservoir layer, forming bonds with oxygen vacancies to reduce their mobility. Reducing oxygen vacancy mobility offers several advantages for analog computing applications, including enhanced device stability, improved retention of resistance states, and more precise control over the device resistance levels. These benefits result in increased accuracy and reliability of analog computations, as well as extended device longevity and reduced susceptibility to environmental factors. Furthermore, this method shows the advantages of utilizing conventional thin film processing techniques such as physical vapor deposition (PVD) and atomic layer deposition (ALD), as well as fab-friendly metal oxides such as hafnium oxides, zirconium oxides, and tungsten oxides, facilitating facile scale-up and cost-effective fabrication.

In addition, the disclosed nitriding treatment enables the tuning of oxygen vacancy mobility without the deposition of an additional material layer. Therefore, this method maintains the original stack thickness of the resistive memory device. The preservation of device dimensions facilitates a more flexible stacking design, especially when high memory storage density is required. The nitriding treatment may increase device adaptability by being applicable to a single interface between the resistive switching layer and the oxygen reservoir layer, or conveniently implemented across multiple interfaces in more complex device structures featuring multiple discrete resistive switching layer and oxygen reservoir layer stackings.

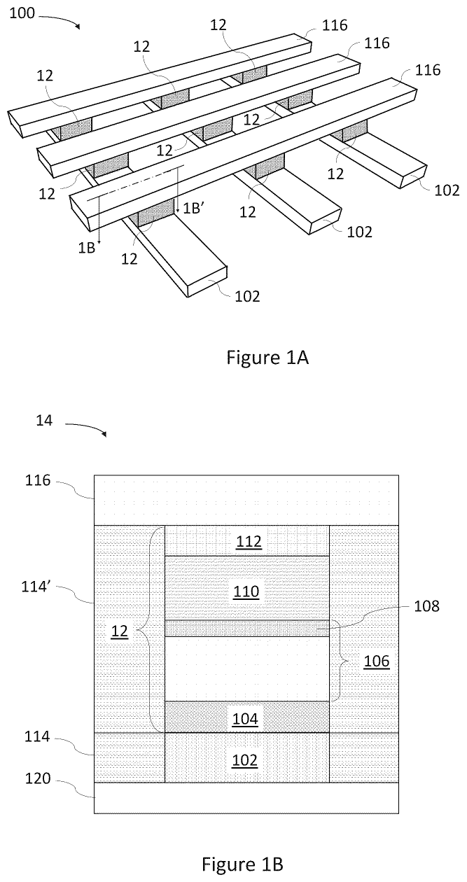

FIG. 1A-1B illustrate a resistive memory in accordance with an embodiment, wherein FIG. 1A illustrates a three-dimensional view of a resistive memory array and FIG. 1B illustrates a cross sectional view of a resistive memory. In particular, FIG. 1B depicts a cross-sectional view along a line 1B-1B′ indicated in FIG. 1A.

FIG. 1A illustrates a three-dimensional view of a resistive memory array 100. The disclosed structure may comprise a plurality of first metal lines (or bit lines) 102 and second metal lines (or word lines) 116 that couple to a plurality of resistive memory devices 12. The first and the second metal lines 102 and 116 may comprise electrically conductive materials such as metals, comprising copper, gold, aluminum, silver, titanium, tungsten, niobium, molybdenum, platinum, tantalum, zirconium, hafnium, lanthanum, ruthenium, palladium, or cobalt. The resistive memory devices 12 may be arranged in a crossbar array configuration, where each device may be coupled to a first metal line 102 and a second metal line 116. The first metal lines 102 may orient along a first direction like horizontal, and may be used to select the rows of the resistive memory array, while the second metal lines 116 may orient along a second direction that may be orthogonal to the first direction and be used to select the columns. This configuration allows for precise addressing and efficient read/write operations of selective resistive memory devices 12 within the resistive memory array 100, enabling high-density and high-performance memory storage.

FIG. 1B illustrates a cross-sectional view of a resistive memory 14 along a line 1B-1B′ indicated in FIG. 1A. In some embodiments, the resistive memory 14 may comprise a first metal line 102 (or bit line) disposed over a substrate 120, a resistive memory device 12 disposed over the first metal line 102, and a second metal line 116 (or word line) disposed over the resistive memory device 12 and a second insulating layer 114′. A first insulating layer 114 and the second insulating layer 114′ may be disposed over the substrate 120 to avoid direct contact between the first metal line 102 and the second metal line 116. Additionally, these insulating layers may isolate different resistive memory devices 12, thereby preventing electrical interference and ensuring reliable operation. This arrangement may preserve the integrity of individual metal lines and mitigate cross-talk or short-circuiting between adjacent memory devices, thus enhancing overall device performance and reliability. The material for the first insulating layer 114 and the second insulating layer 114′ may comprise silicon dioxide, silicon nitride, aluminum oxide, hafnium oxide, tantalum pentoxide, boron nitride, polyimide, low-k dielectrics, silicon carbide, or phosphosilicate glass.

The substrate 120 may be a bulk substrate such as a blank silicon wafer, a silicon-on-insulator (SOI) wafer, or any of various other semiconductor substrates. The substrate 120 may also be coated or layered with any number of additional materials, including compound semiconductors, metal or metal oxides, or metal nitrides. The substrate 120 may include any material portion or structure of a device, particularly a semiconductor or other electronics device.

With respect to the resistive memory device 12, in some embodiments, it may comprise a stack of a first electrode 104 (serving as a bottom electrode), a metal oxide layer 106 (serving as a resistive switching layer), an oxygen reservoir layer 110, and a second electrode 112 (serving as a top electrode). The metal oxide layer 106 may comprise an outer surface 108 which is facing the oxygen reservoir layer 110.

The first electrode 104 and the second electrode 112 may comprise any suitable electrically conductive material, including metals such as cobalt, nickel, copper, aluminum, silver, gold, platinum, iridium, ruthenium, or tungsten; conductive nitrides such as titanium nitride or tantalum nitride; or conductive oxides such as iridium(IV) oxide, ruthenium(IV) oxide, lanthanum strontium cobalt oxide (LSCO), strontium ruthenium oxide (SRO), or lanthanum-doped SRO, according to various embodiments.

The metal oxide layer 106, in some embodiments, may comprise hafnium oxide (HfOₓ, 0≤x≤2), zirconium oxide (ZrOₓ, 0≤x≤2), hafnium zirconium oxide (HfₓZr₁₋ₓO_{z}, 0≤x≤1, 0≤z≤2), tantalum oxide (TaOₓ, 0≤x≤2.5) or titanium oxide (TiOₓ, 0≤x≤2). Metal oxides such as hafnium oxide, zirconium oxide, and hafnium zirconium oxide have several advantages to compose the metal oxide layer 106. These metal oxides exhibit large band gap, high thermal stability, and high compatibility with existing semiconductor manufacturing processes. These materials also have high chemical stability that reduces the likelihood of unwanted side reactions, thereby providing stable performance under aggressive cycling conditions. The metal oxide layer 106 may comprise oxygen vacancies that migrate between adjacent lattice positions under an electric field. The migration of the oxygen vacancies may result in the formation or rupture of a conducting filament formed within the metal oxide layer 106.

In some embodiments, the metal oxide layer 106 may be thick enough to ensure accumulation of oxygen vacancies for uniform formation and rupture of oxygen vacancy conducting filaments, resulting in reliable switching and good data retention. The layer may be thin enough to induce resistance switching under low voltages, leading to low power consumption. In various embodiments, the thickness of the metal oxide layer 106 may be in the range of 1 nm to 10 nm, providing reliable switching behavior, low power operation, and robust data retention. In some embodiments, the metal oxide layer 106 may comprise an outer surface 108 comprising a concentration of nitrogen where the nitrogen profile drops from the surface into the metal oxide layer 106. The incorporated nitrogen may reduce the oxygen vacancy mobility within the metal oxide layer 106 and optimize RRAM devices for analog computing applications with more controlled and predictable resistance changes.

The oxygen reservoir layer 110, in some embodiments, may be a multivalent metal oxide with high affinity to oxygen and comprise tungsten oxide (WOₓ, 0≤x≤3). The high affinity to oxygen improves the ability of the metal oxide to release and absorb oxygen ions as needed, maintaining an optimal concentration of oxygen vacancies for reliable device performance. The physical mechanisms are related to oxygen exchange between the conductive filament in the resistive switching metal oxide layer and the oxygen reservoir layer involving interface oxygen exchange, drift through grain boundaries and defects, and valence change in the oxygen reservoir layer. Metal oxides such as tungsten oxide (WOₓ, 0≤x≤3) show several advantages to compose the oxygen reservoir layer 110. Tungsten oxide is chemically stable and can maintain its structure while providing oxygen ions efficiently. This stability ensures that the oxygen reservoir layer remains effective over many switching cycles. Moreover, it can withstand the high temperatures during the fabrication of semiconductor devices without decomposing or losing its functional properties.

The oxygen reservoir layer 110 may be disposed adjacent to the metal oxide layer 106 to regulate the availability of oxygen vacancies and provide a dynamic oxygen source. This arrangement may facilitate the migration of oxygen vacancies by either releasing or absorbing oxygen ions from the metal oxide layer 106 as needed. During the formation of conducting filaments in the metal oxide layer 106, oxygen vacancies may migrate and aggregate to form these filaments. The oxygen reservoir layer 110 may release oxygen ions when necessary to maintain an optimal concentration of oxygen vacancies, thereby stabilizing the conductive pathways. This controlled release and absorption of oxygen ions help maintain consistent switching behavior, improving both the reliability and endurance of the RRAM device. In some embodiments, the thickness of the oxygen reservoir layer 110 may comprise 1 nm to 10 nm, providing reliable oxygen control, low power operation, and robust data retention.

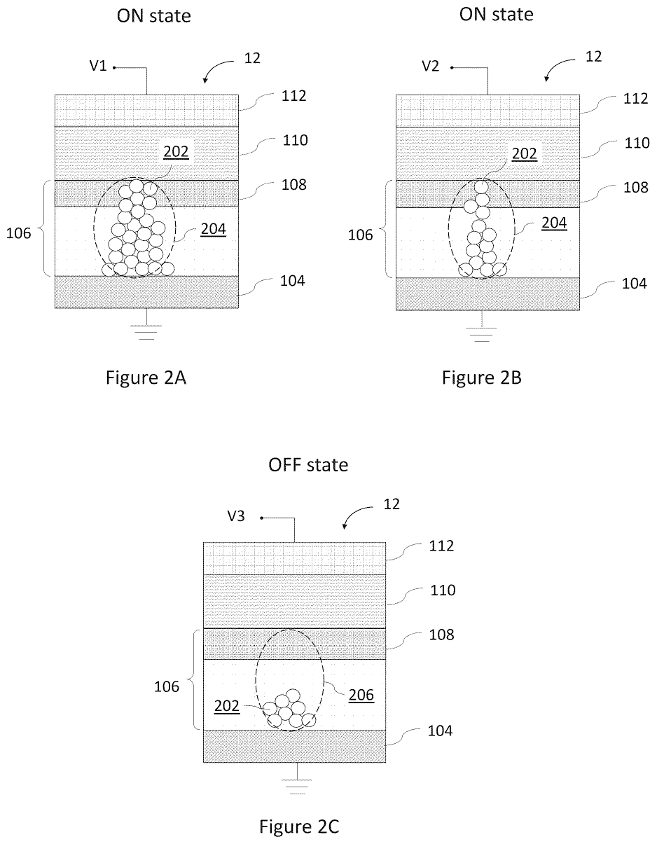

FIGS. 2A-2C illustrate responses of the resistive memory device 12 current states and oxygen vacancy filaments in the metal oxide layer 106 (serving as resistive switching layer) to applied electrical signals. In some embodiments, an electrical signal, such as voltage, may be applied between the first electrode 104 and the second electrode 112 that changes the resistance of the metal oxide layer 106. In one example, a forward voltage V1 may be applied to the second electrode 112 and the first electrode 104 may be grounded. The forward voltage V1 may generate an electric field in the device 12 that may drive the oxygen vacancies 202 aggregating and forming one or more electrically conductive oxygen vacancy filaments 204, penetrating the metal oxide layer 106. The formation of conducting filaments may reduce the resistance of the resistive memory device 12, transitioning it to an ON state, characterized by an output current. By tuning the aggregation of oxygen vacancies 202, the quantity of the oxygen vacancy filaments 204 and their corresponding diameters may be adjusted, which may modify the resistance and output current of the memory device. For example, a lower forward voltage V2 (where V2<V1) may result in reduced aggregation of oxygen vacancies 202 in the metal oxide layer 106, leading to formation of an oxygen vacancy filament 204 with reduced diameter. Moreover, the lower forward voltage V2 may also reduce the quantity of conducting filaments that connect the first electrode 104 and the second electrode 112. This corresponds to a higher resistance and a lower output current from the resistive memory device 12. In this state, the device remains ON but with a reduced output current. Additionally, when the applied voltage changes to a reverse voltage V3, the oxygen ions in the oxygen reservoir layer 110 may diffuse into the metal oxide layer 106 and combine with oxygen vacancies 202, resulting in a filamentary rupture 206. This may switch the resistive memory device 12 to an OFF state, characterized by reduced or zero output current. The controlled manipulation of these oxygen vacancies may correspond to different data storage states or output signals, and improves the reliable operation of resistive memory devices, enabling non-volatile data storage through resistive switching mechanisms.

In some embodiments, the metal oxide layer 106 may be exposed to a nitriding surface treatment (or nitridation) that may form an outer surface 108 (or nitridated surface). The outer surface 108 may be a portion of the metal oxide layer 106 and characterized with an incorporation of nitrogen atoms that forms a nitrogen profile with nitrogen concentration dropping from the surface into the metal oxide layer 106. The incorporated nitrogen atoms may form VNₓ complexes (V represents oxygen vacancy) with oxygen vacancies without forming a nitride compound. The formation of VNₓ complexes may effectively reduce the diffusivity of oxygen vacancies in the metal oxide layer 106. The reduced oxygen vacancy mobility may suppress abrupt resistance state change by slowing down or suppressing the formation and rupture of one or more conducting filaments, thereby creating more intermediate resistance states and may also induce formation of additional conducting filaments resulting in different resistance in the ON state. These versatile resistance states may be applied to emulate synaptic weights for application in neuromorphic computing systems. The reduction in oxygen vacancy flux into the metal oxide layer 106 may maintain consistent resistance levels, thereby enhancing the fidelity of analog computations.

In some embodiments, operating the resistive memory device 12 may involve applying various voltages between the first electrode 104 and the second electrode 112 to induce changes in the resistive state of the metal oxide layer 106, which subsequently affects the output current. In forward bias, a sufficient positive voltage may be applied, oxygen vacancies in the metal oxide layer 106 may aggregate and form one or more conducting filaments, transitioning the device from a high-resistance state (HRS) to a low-resistance state (LRS). This transition may be characterized as an increase in the output current, allowing the device to represent a “write” operation in digital applications or adjust the weight in analog applications, such as neuromorphic computing. Conversely, a reverse bias or a negative voltage may be applied that may cause the conducting filaments to rupture or dissolve, reverting the device back to the HRS. This results in a decrease in the output current, corresponding to an “erase” operation in digital contexts or a reduction in synaptic strength in analog computing scenarios. The ability to finely tune these resistance states through precise control of applied voltages may improve performance of RRAM device in analog applications, where varying resistance levels may be applied for arithmetic operations, signal processing, and emulating neural network behaviors.

In some embodiments, the disclosed resistive memory device 12 may integrate with a transistor to form an 1T-1R memory cell comprising a single transistor (1T) and a single memory device (1R) connected in series. The transistor may serve as an access device, controlling the read and write operations to the resistive memory device 12. This integration may enhance the precise control of current flowing through the resistive memory device 12, thereby improving the reliability and performance of the memory cell. In some embodiments, the transistor may comprise metal-oxide-semiconductor field-effect transistors (MOSFETs), thin-film transistors (TFTs), organic field-effect transistors (OFETs), Indium-Gallium-Zinc-Oxide transistors (IGZO FETs), or two-dimensional material-based field-effect transistors (2D FETs) such as molybdenum disulfide (MoS₂) field-effect transistors (FETs). The formation of the 1T-1R memory cell may provide a scalable solution for high-density memory applications, offering advantages in terms of reduced power consumption, improved switching speed, and enhanced data retention.

In some embodiments of operating the 1T-1R memory cell, the single transistor (1T) and the single resistive memory device (1R) may be connected in series, where the transistor may serve as an access device controlling the read and write operations to the resistive memory device 12. The control signal may be applied to the gate terminal of the transistor that may allow current to flow through the circuit, enabling the selection of the resistive memory device 12. During write operations, a forward voltage may create an electric field that induces the migration and aggregation of oxygen vacancies within the metal oxide layer 106, forming one or more conducting filaments and transitioning the device from a high-resistance state (HRS) to a low-resistance state (LRS). Conversely, a reverse voltage may cause these filaments to rupture, reverting the device back to HRS. The transistor may precisely modulate current flow during these operations to prevent damage and excessive power consumption. In read operations, a lower voltage may be applied, and the transistor may connect the resistive memory device 12 to the read circuitry; the current level corresponds to the resistance state of the RRAM, enabling non-destructive readout. This 1T-1R configuration may enhance switching speeds, reduce power consumption, and improve data retention and endurance, providing a scalable solution for high-density memory applications with advanced performance and reliability.

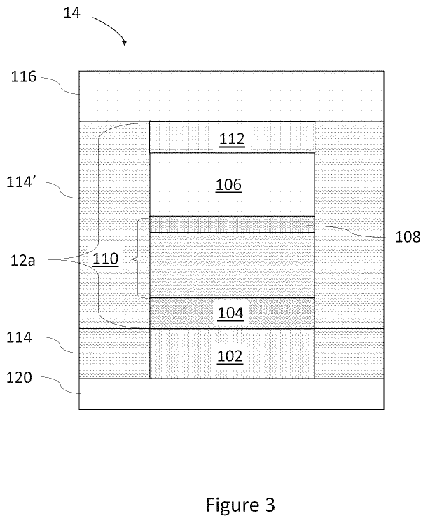

In one variation, as illustrated in FIG. 3, the resistive memory 14 may comprise a resistive memory device 12a comprising an alternative layer sequence. In some embodiments, the resistive memory 14 may comprise the first metal line 102 disposed over the substrate 120, the resistive memory device 12a disposed over the first metal line 102, and the second metal line 116 disposed over the resistive memory device 12a and the second insulating layer 114′. The first insulating layer 114 and the second insulating layer 114′ may be disposed over the substrate 120 to prevent the direct contact between the first metal line 102 and the second metal line 116. These insulating layers may isolate different resistive memory devices 12a to prevent electrical interference. The resistive memory 14 may respectively comprise the materials, structures, and/or other components described above with reference to corresponding parts of FIG. 1B. The resistive memory device 12a, in some embodiments, may comprise a stack of the first electrode 104 (serving as the bottom electrode), the oxygen reservoir layer 110, the metal oxide layer 106, and the second electrode 112 (serving as the top electrode). The outer surface 108 of the oxygen reservoir layer 110 may exhibit a nitrogen concentration profile in which the nitrogen concentration decreases from the surface into the interior of the oxygen reservoir layer 110. The resistive memory device 12a may respectively comprise the materials, structures, and/or other components described above with reference to corresponding parts of FIG. 1B. The variation in layer sequence may contribute to a better flexibility in device design and integration with additional functional layers, such as barrier layers or conductive interlayers, to further enhance device performance by meeting specific requirements.

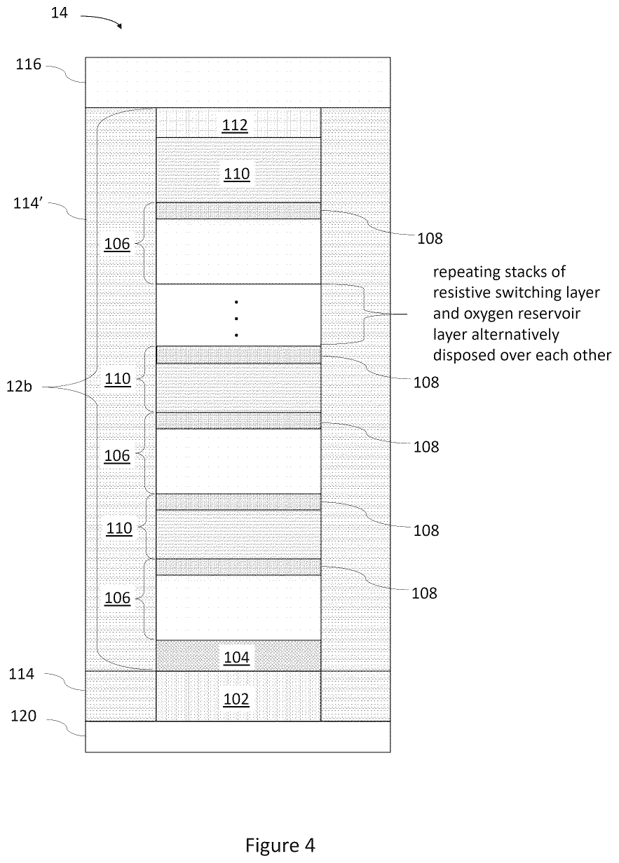

In another variation, as illustrated in FIG. 4, the resistive memory 14 may comprise a resistive memory device 12b comprising a plurality of the metal oxide layers 106 and the oxygen reservoir layers 110 disposed over each other alternatively. In some embodiments, the resistive memory 14 may comprise the first metal line 102 disposed over the substrate 120, the resistive memory device 12b disposed over the first metal line 102, and the second metal line 116 disposed over the resistive memory device 12b and the second insulating layer 114′. The first insulating layer 114 and the second insulating layer 114′ may be disposed over the substrate 120 to prevent the direct contact between the first metal line 102 and the second metal line 116. Additionally, these insulating layers may isolate different resistive memory devices 12b, thereby preventing electrical interference and ensuring reliable operation. The resistive memory 14 may respectively comprise the materials, structures, and/or other components described above with reference to corresponding parts of FIG. 1B.

In some embodiments, the resistive memory device 12b may comprise the first metal oxide layer 106 disposed over the first electrode 104 (serving as the bottom electrode), following with repeated stacks of the oxygen reservoir layers 110 and the metal oxide layers 106 alternatively disposed over each other between the first electrode 104 and the second electrode 112 (serving as the top electrode). The second electrode 112 may be disposed over the oxygen reservoir layer 110. The resistive memory device 12b may respectively comprise the materials, structures, and/or other components described above with reference to corresponding parts of FIG. 1B. In some embodiments, a plurality of the metal oxide layer 106 and the oxygen reservoir layer 110 may be subjected to a nitriding surface treatment, forming a plurality of outer surfaces 108 that incorporate nitrogen atoms. Each outer surface 108 may be positioned at the interface between the corresponding metal oxide layer 106 and oxygen reservoir layer 110. The incorporation of nitrogen atoms within these surfaces may retard the diffusion of oxygen vacancies across the interfaces formed by these layers.

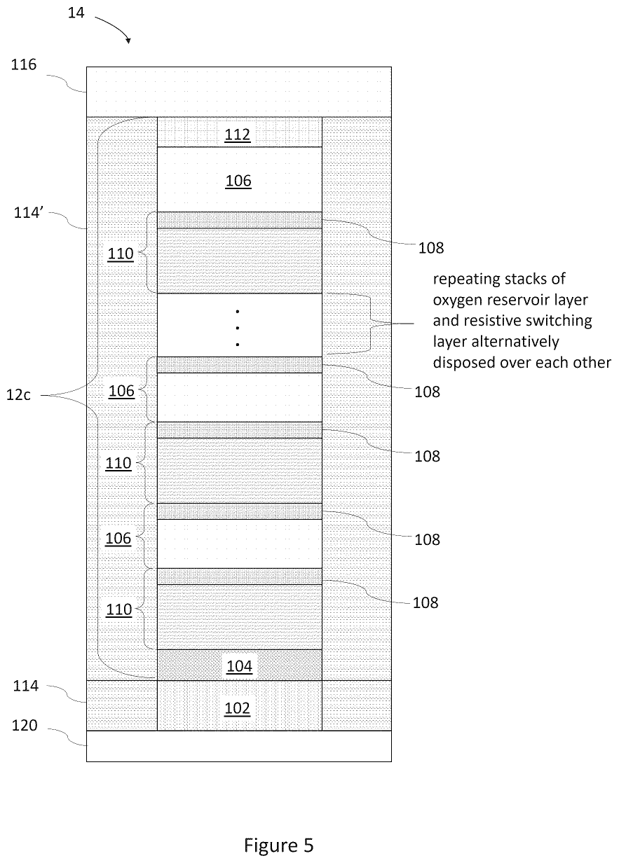

In a third variation, as illustrated in FIG. 5, the resistive memory 14 may comprise a resistive memory device 12c comprising a plurality of the oxygen reservoir layers 110 and the metal oxide layers 106 disposed over each other alternatively. In some embodiments, the resistive memory 14 may comprise the first metal line 102 disposed over the substrate 120, the resistive memory device 12c disposed over the first metal line 102, the second metal line 116 disposed over the resistive memory device 12c and the second insulating layer 114′. The first insulating layer 114 and the second insulating layer 114′ may be disposed over the substrate 120 to prevent the direct contact between the first metal line 102 and the second metal line 116. The insulating layers may isolate different resistive memory devices 12c to prevent electrical interference. The resistive memory 14 may respectively comprise the materials, structures, and/or other components described above with reference to corresponding parts of FIG. 1B. In some embodiments, the resistive memory device 12c may comprise the oxygen reservoir layer 110 disposed over the first electrode 104 (serving as the bottom electrode), following with repeated stacks of the metal oxide layers 106 and the oxygen reservoir layers 110 alternatively disposed over each other between the first electrode 104 and the second electrode 112 (serving as the top electrode). The second electrode 112 may be disposed over the metal oxide layer 106. In some embodiments, the metal oxide layer 106 and the oxygen reservoir layer 110 may be exposed for a nitriding surface treatment process that may form the outer surface 108 comprising nitrogen atoms to control oxygen vacancy mobility. The resistive memory device 12c may respectively comprise the materials, structures, and/or other components described above with reference to corresponding parts of FIG. 1B.

One advantage of the nitriding surface treatment process may be preventing the deposition of additional material layers to control oxygen vacancy mobility, thus minimizing device size and reducing cost. The configuration with a plurality of the metal oxide layer 106 and the oxygen reservoir layer 110 may facilitate improved control over the migration of oxygen vacancies, enabling a more precise modulation of resistance states, which improves the resolution and accuracy in analog computing application. In addition, it may allow for increased scalability and integration density by supporting three-dimensional stacking, thereby optimizing the use of available substrate area and enhancing the overall storage capacity of the RRAM device.

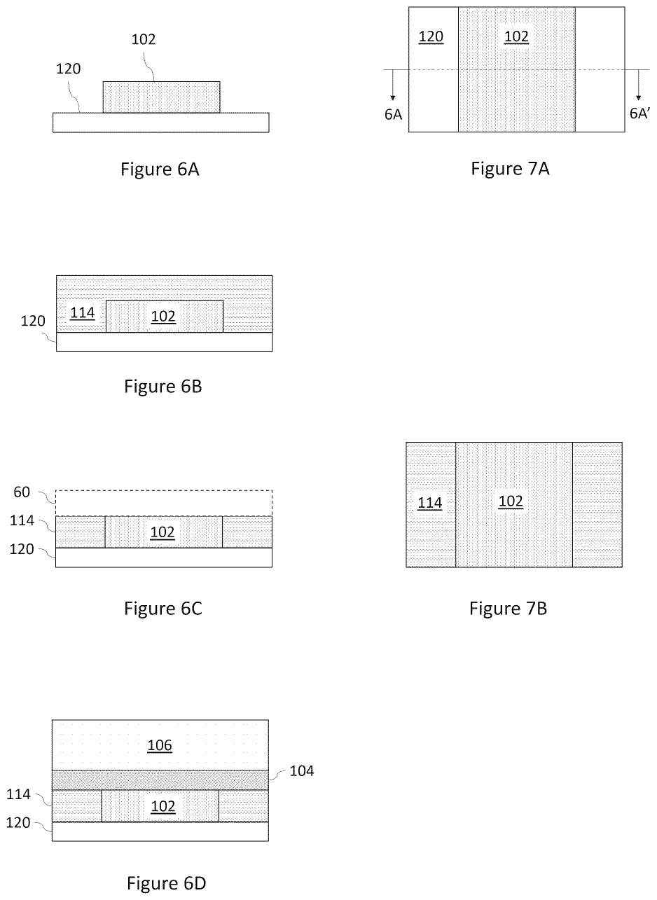

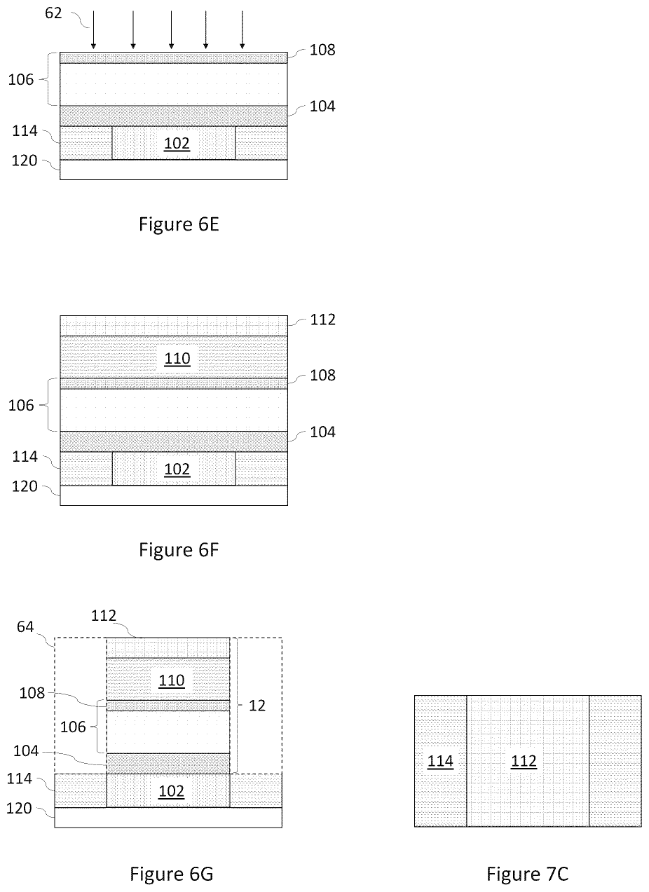

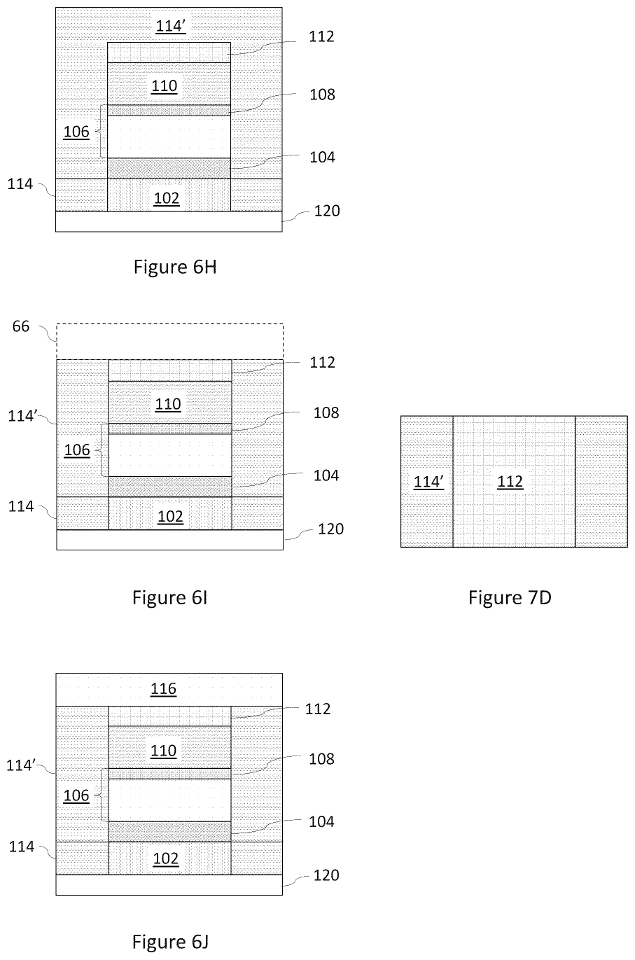

FIGS. 6A-6J and 7A-7D respectively illustrate cross-sectional and top-down views of forming the resistive memory 14, in accordance with an embodiment. The cross-sectional view in FIG. 6A corresponds to a line 6A-6A′ indicated in FIG. 7A. Like reference numerals are used to refer to identical features in the two sets of figures.

With reference to FIGS. 6A and 7A, and according to an embodiment, the first metal line 102 may be formed by depositing over the substrate 120. The substrate 120 and the first metal line 102 may respectively comprise the materials, structures, and/or other components described above with reference to corresponding parts of FIG. 1B.

The first metal line 102 may comprise electrically conductive materials such as copper, aluminum, silver, gold, or platinum. In one embodiment, the first metal line 102 may comprise copper deposited using an additive process such as a damascene or dual damascene process. In other embodiment, the first metal line 102 may comprise aluminum deposited using a subtractive deposition process where a layer of aluminum is deposited and etched. Accordingly, the first metal line 102 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

Next, referring to FIG. 6B, the first insulating layer 114 may be formed by depositing over the first metal line 102 and the substrate 120. The first insulating layer 114 may comprise the materials described above with reference to FIG. 1B and may be deposited using any suitable deposition technique, such as any of the techniques from the list provided in the previous paragraph. In some embodiments, the first insulating layer 114 may be silicon oxide deposited by metal-organic CVD using tetraethyl orthosilicate (TEOS). In some embodiments, the first insulating layer 114 may be silicon nitride deposited by plasma-enhanced CVD using dichlorosilane.

Next, and with reference to FIGS. 6C and 7B, a portion 60 of the first insulating layer 114 may be etched. The portion 60 may be sufficiently deep that it reveals an upper surface of the first metal line 102. According to various embodiments, the portion 60 may be etched by etching method, such as wet etching methods comprising hydrofluoric acid, potassium hydroxide, phosphoric acid, nitric acid, ammonium hydroxide, sulfuric acid, hydrogen peroxide, or dry etching methods such as inductively coupled plasma etching (ICPE), reactive-ion etching (RIE), deep reactive-ion etching (DRIE), electron cyclotron resonance etching (ECRE), ion beam etching (IBE), neutral beam etching (NBE), or any other etching process or combination thereof.

With reference to FIG. 6D, and according to an embodiment, a layer stack may be formed by depositing the first electrode 104 over the first metal line 102 and the first insulating layer 114, then depositing the metal oxide layer 106 over the first electrode 104. The first electrode 104 and the metal oxide layer 106 may respectively comprise the materials, structures, and/or other components described above with reference to corresponding parts of FIG. 1B.

The first electrode 104 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

The metal oxide layer 106 may be deposited using any suitable deposition technique from the list provided in the previous paragraph. In one example, PVD technique may be used to deposit the metal oxide layer 106 comprising hafnium oxide, zirconium oxide, or hafnium zirconium oxide. At least one of sputtering targets comprising high-purity hafnium (99.99%), high-purity zirconium (99.99%), hafnium dioxide (99.9%), or zirconium dioxide (99.9%) may be introduced into a process chamber. Afterwards, a reactive gas mixture comprising argon and oxygen, at a ratio of 1:10 to 10:1 may be flowed into the process chamber at a rate of 2 to 1000 sccm with a chamber pressure of 0.1-10 mTorr. The argon and oxygen ratio may be tuned to control the amount of oxygen vacancies in the deposited oxide film. Then a direct current (DC) or radio frequency (RF) power may be applied to the sputtering target with controlled power level to achieve a discharge power between 50 W and 1500 W. A plasma may be generated and comprise oxygen ions, and argon ions.

The metal oxide layer 106 comprising hafnium, zirconium, or oxygen may be deposited by PVD over the first electrode 104 with a temperature ranging from room temperature to 400° C.

In some embodiments, nitrogen-containing gases comprising hydrogen, nitrogen, ammonia, hydrazine, or nitrous oxide may be added into the reactive gas mixture. The nitrogen may be introduced from the beginning but in many embodiments, the nitrogen may be introduced towards the end of the deposition after a bulk of the film has been deposited. In embodiments introducing nitrogen, the plasma may comprise reactive nitrogen species or nitrogen ions. In such embodiments, the nitrogen-containing plasma may interact with the sputtering target and the resulted nitrogen atoms may be incorporated into the deposited metal oxide thin film, leading to an in-situ nitridation. The nitrogen profile of the metal oxide layer 106 may be controlled by adjusting the concentration, duration, and other parameters of nitrogen-containing gases. The process of in-situ nitridation during the metal oxide layer deposition may lead to the simultaneous incorporation of nitrogen atoms into the metal oxide layer 106. The process may result in a more uniform distribution of the nitrogen atoms throughout the oxide matrix. Furthermore, in-situ nitridation may facilitate the incorporation of the nitrogen at the atomic level. This method may allow for the simultaneous optimization of the oxide growth parameters and nitrogen concentration, thereby streamlining the fabrication process and reducing the likelihood of contamination or damage to the oxide film that may occur if applying subsequent procedures.

In various embodiments, the metal oxide layer 106 may be annealed after deposition using methods comprising rapid thermal process, furnace annealing, or other suitable annealing method. For example, the annealing method may be a rapid thermal process carried out between 300° C. and 800° C. for 1 s to 60 s. The thermal treatment may enhance the electronic properties by improving the crystallinity of the deposited layer, reducing defects and dislocations.

In another example, ALD technique may be used for depositing the metal oxide layer 106 comprising hafnium oxide, zirconium oxide, or hafnium zirconium oxide. The process may comprise the sequential introduction of at least one of the hafnium precursor and zirconium precursor and an oxidizing reactant into a process chamber under controlled conditions. A pulse of metal precursors comprising tetrakis(dimethylamino)hafnium (TDMAH), tetrakis(ethylmethylamino)hafnium (TEMAH), tetrakis(diethylamido)hafnium (TDEAH), tris(dimethylamino)cyclopentadienyl hafnium (CpHf(NMe₂)₃), tetrakis(dimethylamido)zirconium (TDMAZ), tetrakis(ethylmethylamido)zirconium (TEMAZ), tetrakis(diethylamido)zirconium (TDEAZ), or tris(dimethylamino)cyclopentadienyl zirconium (CpZr(NMe₂)₃) may flow into the process chamber at a temperature range of approximately 200° C. to 400° C. and a pressure ranging from 0.1 to 1 Torr. The precursor may adsorb on the substrate surface, forming a self-limited layer.

A purge step using an inert gas, such as argon and nitrogen, may be followed to remove excess precursors. Subsequently, an oxidizing reactant comprising water vapor, oxygen, ozone, and other gases may be introduced to the chamber. A plasma may be generated and comprise oxygen ions, argon ions, or reactive oxygen species. The plasma may be generated using a power source set to a frequency and power level, for example, in the range of 1-20 MHz and 50-1500 W. The oxidizing reactant may react with the adsorbed metal precursors, forming a monolayer of metal oxide comprising hafnium, zirconium, or oxygen.

Another purge step using an inert gas, such as argon and nitrogen, may be followed to remove excess reactants and by-products. Because each ALD cycle may deposit a sub-monolayer of material, the ALD cycle may be repeated until achieving the desired thickness for the metal oxide layer 106 which may range from 1 nm to 10 nm, according to various embodiments. The composition of the metal oxide film may be controlled by adjusting the composition, duration, and other parameters of the metal precursor pulses and oxidizing reactant pulses.

In some embodiments, the nitrogen-containing gases in the oxidizing reactant may allow for simultaneous nitrogen incorporation into the metal oxide layer 106 during the oxide growth process (or in-situ nitridation). In such embodiments, a nitrogen containing gas such as nitrogen, ammonia, hydrazine, or nitrous oxide may be injected into the process chamber.

In some embodiments, the deposited oxides thin film may be annealed comprising rapid thermal process, furnace annealing, or other suitable annealing method. For example, the annealing method may be a rapid thermal process carried out between 300° C. and 800° C. for 1 s to 60 s.

Next, with reference to FIG. 6E, a nitriding surface treatment process 62 may be applied to the outer surface 108 of the metal oxide layer 106. The nitriding surface treatment process 62 may comprise plasma treatment, ion implantation, thermal treatment, hydrothermal treatment, or spin-on dopant doping. In one embodiment, nitriding process may be achieved by introducing a nitrogen-containing gas comprising argon, hydrogen, nitrogen, ammonia, hydrazine, or nitrous oxide, into a process chamber. In various embodiments, the process chamber may be the same chamber used to perform the ALD deposition or the plasma deposition described above.

The chamber used for the nitriding treatment may be maintained at a temperature range of room temperature to 400° C. and a pressure range of 0.1 to 10 Torr. The nitrogen-containing gas may be introduced at a flow rate of 2 to 1000 sccm. Afterwards, a plasma generation may be employed to activate the nitrogen-containing gas that may comprise nitrogen-based plasma. The plasma may be generated using a power source set to a specific frequency and power level, for example, in the range of 1-20 MHz and 50-1500 W. The metal oxide layer 106 may be exposed to the plasma for a duration of 0.1 to 60 minutes to incorporate the nitrogen atoms into the metal oxide lattice, resulting in a nitrogen profile in the outer surface 108, wherein a concentration of the nitrogen drops from the surface into the metal oxide layer 106. The nitrogen atoms may diffuse into the metal oxide layer with a depth of 0.1 nm to 10 nm from the surface. The use of nitrogen-based plasma for nitriding surface treatment may provide several advantages. Plasma generation may facilitate the dissociation of the nitrogen gas precursor into reactive species, thereby enhancing the incorporation of nitrogen into the metal oxide lattice. This method may achieve a more uniform and controlled concentration profile, improving the accuracy of oxygen vacancy mobility control. Additionally, the plasma-assisted nitriding process may operate at relatively lower temperatures compared to conventional thermal annealing methods, thereby minimizing thermal stress and potential damage to the thin film substrate, and meeting thermal budget requirements.

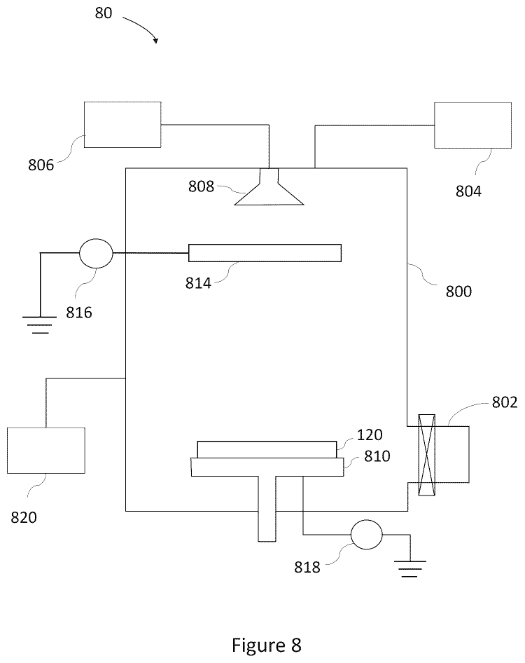

FIG. 8 illustrates a process chamber 80 that may be used for the nitriding surface treatment process 62 described in previous paragraph. The process chamber 80 may be enclosed by a chamber wall 800 that may comprise stainless steel or ceramics to provide high structural integrity and corrosion resistance.

A vacuum pumping system 802 may comprise a turbomolecular pump and a rotary pump to maintain a low-pressure environment of the chamber. A temperature controller 804 may comprise thermocouples and heaters comprising high-temperature alloys or ceramics to maintain precise temperature control within the process chamber 80.

A gas controller 806 may be equipped with precision valves to control the types, flow rates, durations of specific gases introduced into the chamber. The gases may comprise metal-organic precursors, argon, oxygen, ozone, water vapor, hydrogen, nitrogen, ammonia, hydrazine, or nitrous oxide. The gas controller 806 may be coupled with a gas outlet 808, which may have a showerhead design with a plurality of outlets to provide an even distribution of gases across the chamber. This design may enhance the homogeneity of gas distribution in the chamber, leading to a uniform nitriding surface treatment process on the substrate 120.

A rotating substrate holder 810 may provide mechanical support as well as electrical coupling to a substrate while rotating the substrate during the processing. The rotating substrate holder 810 may comprise stainless steel, copper, aluminum, molybdenum, graphite or ceramics. The rotating substrate holder 810 may be thermally conductive and coupled with thermocouples and heaters that ensure uniform heating of the substrate 120. The rotating speed of the substrate holder 810 may be adjusted during the nitriding process to expose all areas of the substrate 120 to the nitrogen-based plasma, thereby enhancing the uniformity and effectiveness of the nitriding treatment.

An upper electrode 814 may be disposed within the process chamber 80 and may comprise high-conductive materials such as copper, aluminum, stainless steel, molybdenum, or graphite. The upper electrode 814 may be connected to a source power 816 comprising a direct current (DC) or radio frequency (RF) power supply. The substrate holder 810 may be connected with a bias power 818 comprising a direct current (DC) or radio frequency (RF) power supply. The bias power 818 at the substrate holder 810 may enhance modulation precision of ion energy at the substrate surface, ensuring that ions are adequately energized to facilitate effective nitrogen incorporation without causing substrate damage. Meanwhile, the source power 816 at the upper electrode 814 may sustain a stable and uniform plasma, which may interact synergistically with the bias-enhanced ion energy at the substrate. This dual-power configuration may result in better plasma control, leading to more uniform and efficient nitriding process, ultimately enhancing the quality and reliability of the treated layers. A real-time monitoring system 820 may be introduced for dynamic adjustments to maintain optimal process conditions. The real-time monitoring system 820 may integrate with an in-situ optical emission spectroscopy (OES) or mass spectrometry that provides continuous feedback on plasma composition and surface reactions on the substrate 120. This real-time data may communicate with other chamber controllers such as the temperature controller 804, the gas controller 806, the source power 816, the bias power 818, and the substrate holder 810, to perform immediate adjustments to gas flow rates, plasma power, substrate temperature or rotating speed, ensuring consistent and high-quality nitriding surface treatment.

The nitriding surface treatment process 62 exhibits many advantages for RRAM device fabrication and commercial application. The nitriding depth and the nitrogen concentration in the metal oxide layer 106 may be precisely controlled through exposing time, temperature, nitrogen-containing precursor species, concentrations, etc. These conditions may be finely tuned to achieve desired control of oxygen vacancy mobility to optimize the device analog computing performance. Moreover, the nitriding process may integrate with conventional thin film techniques such as ALD and PVD, which have a well-established and reliable framework for precise control over thickness and uniformity. Furthermore, the extensive knowledge and historical data associated with conventional thin film techniques may facilitate the optimization and troubleshooting of the process, thereby reducing development time and costs. Additionally, the compatibility of these techniques with a wide range of materials and substrates may enhance the versatility and applicability of the nitriding process across various industrial applications.

In addition to the nitriding surface treatment on the metal oxide layer 106 described with reference to FIG. 6E, it should be understood that this treatment may similarly be applied to other layers within the resistive memory device. This includes, but is not limited to, additional metal oxide layers, oxygen reservoir layers, or any interface layers where the incorporation of nitrogen atoms via a nitriding surface treatment would be beneficial. Applying the nitriding surface process to these layers can enhance the device's overall stability by further controlling oxygen vacancy diffusion and improving the reliability and performance of the resistive memory device. The method and conditions for the nitriding treatment remain consistent with those previously detailed.

With reference to FIG. 6F, and according to an embodiment, the oxygen reservoir layer 110 may be disposed over the metal oxide layer 106, and the second electrode 112 may be disposed over the oxygen reservoir layer 110. The oxygen reservoir layer 110 and the second electrode 112 may respectively comprise the materials, structures, and/or other components described above with reference to corresponding parts of FIG. 1B.

The oxygen reservoir layer 110 and the second electrode 112 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal- organic CVD; low-pressure CVD; rapid thermal CVD; electrodeposition; or any other layer deposition process or combination thereof.

In one example, PVD technique may be used to deposit the oxygen reservoir layer 110 comprising tungsten oxide. A sputtering target comprising high-purity tungsten metal (99.99%) or tungsten oxide (99.99%) may be introduced into a process chamber. Afterwards, a reactive gas mixture, comprising argon and oxygen, at a ratio varying from 1:10 to 10:1 may be flowed into the process chamber at a rate of 2 to 1000 sccm with chamber pressure in the range of 0.1-10 mTorr. The argon and oxygen gas mixture ratio in a range from 1:10 to 10:1 may be controlled to obtain desired oxygen vacancy concentration in the tungsten oxide thin film. A direct current (DC) or radio frequency (RF) power may be applied to the target that may generate plasma and initiate the sputtering process. The power level may be controlled to achieve a discharge power between 50 W and 1500 W. The tungsten oxide thin film may be deposited over the metal oxide layer 106 with a temperature ranging from room temperature to 400° C. The tungsten oxide thin film may be annealed after deposition using methods comprising rapid thermal process, furnace annealing, or other suitable annealing method. In one example, the annealing method may be a rapid thermal process carried out between 300° C. and 800° C. for 1 s to 60 s.

In another example, ALD technique may be used to deposit the oxygen reservoir layer 110 comprising tungsten oxide. The process may comprise a sequential introduction of a tungsten precursor and an oxidizing reactant into a process chamber under controlled conditions. A pulse of tungsten hexafluoride (WF₆) or a metalorganic tungsten precursor such as tungsten hexacarbonyl (W(CO)₆), bis(tert-butylimido)bis(N, N′-diisopropylacetamidinato)tungsten (W(N^{t}Bu)₂(ⁱPrAMD)₂), bis(tert-butylimido)-bis(dimethylamido)tungsten (W(N^{t}Bu)₂(NMe₂)₂), bis(cyclopentadienyl)tungsten dihydride (WH₂Cp₂), bis(isopropylcyclopentadienyl)tungsten dihydride (WH₂(ⁱPrCp)₂) or hexakis(dimethylamido)ditungsten (W₂(NMe₂)₆) may flow into the process chamber at a temperature range of approximately 150° C. to 400° C. at a pressure ranging from 0.1 to 1 Torr. The precursor may adsorb on the substrate surface, forming a self-limited layer. Subsequently, a purge step using an inert gas, such as argon and nitrogen, may be applied to remove excess precursor. Afterwards, an oxidizing reactant comprising water vapor, oxygen, or ozone may be introduced to the chamber. A plasma may be generated using a power source set to a frequency and power level, for example, in the range of 12-14 MHz and 100-300 W. A second purge step using an inert gas, such as argon and nitrogen, may be applied to remove excess reactants and by-products. The ALD cycle may be repeated until achieving the desired thickness for the oxygen reservoir layer 110 which may range from 1 nm to 10 nm, according to various embodiments. The composition of the metal oxide film may be controlled by adjusting the concentration, species, duration, and other parameters of the tungsten precursor and the oxidizing reactant pulses. In some embodiments, the deposited oxides may be annealed comprising rapid thermal process, furnace annealing, or other suitable annealing method. For example, the annealing process may involve heating the substrate to temperatures ranging from 400° C. to 700° C. for a duration of 30 minutes to several hours, in an environment comprising oxygen, argon or nitrogen.

Next, and with reference to FIGS. 6G and 7C, a layer stack comprising the first electrode 104, the metal oxide layer 106, the oxygen reservoir layer 110 and the second electrode 112 may be patterned and etched wherein the etched stack comprises a portion 64. The patterning and etching may be performed by any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, high-numerical aperture EUV (high-NA EUV), or deep UV (DUV) lithography, in combination with any etching method, such as wet etching methods comprising hydrofluoric acid, potassium hydroxide, phosphoric acid, nitric acid, ammonium hydroxide, sulfuric acid, hydrogen peroxide, and dry etching technique such as inductively coupled plasma etching (ICPE), reactive-ion etching (RIE), deep reactive-ion etching (DRIE), electron cyclotron resonance etching (ECRE), ion beam etching (IBE), neutral beam etching (NBE), or any other etching process or combination thereof. The portion 64 may be etched sufficiently deep that it reveals an upper surface of the first insulating layer 114.

Next, referring to FIG. 6H, the second insulating layer 114′ may be formed by depositing over the second electrode 112 and the first insulating layer 114. The second insulating layer 114′ may comprise the same composition with the first insulating layer 114 as described with reference to FIG. 6B. The second insulating layer 114′ may be deposited using any of the deposition methods described with reference to FIG. 6B for depositing the first insulating layer 114.

Next, and with reference to FIGS. 6I and 7D, a portion 66 of the second insulating layer 114′ may be etched. The portion 66 may be etched sufficiently deep that it reveals an upper surface of the second electrode 112. According to various embodiments, the portion 66 may be etched using any of the etching methods described with reference to FIG. 6C for etching portion 60.

Now referring to FIG. 6J, and according to an embodiment, the second metal line 116 may be formed by depositing over the second electrode 112 and the second insulating layer 114′. The second metal line 116 may comprise the materials, structures, and/or other components described above with reference to corresponding parts of FIG. 1B. The second metal line 116 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; electrodeposition; or any other layer deposition process or combination thereof.

The formation steps described above with reference to FIGS. 6A-6J and 7A-7D may be combined or adapted to various other device configurations. These steps are designed with versatility in mind, allowing their application across different embodiments to achieve similar functional outcomes. For example, certain deposition techniques, lithography techniques, etching methods, or surface treatments detailed herein can be utilized interchangeably or in combination with other layers and materials to create alternative device configuration. This flexibility ensures that the described techniques enhance the performance, reliability, and manufacturability of a wide range of memory devices, thereby expanding the scope and applicability of the invention across various technological implementations.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A resistive memory comprising:
a first metal line oriented along a first direction;
a first electrode coupled to the first metal line and disposed over the first metal line;
a second electrode disposed over the first electrode;
a first metal oxide layer disposed between the first electrode and the second electrode;
a first oxygen reservoir layer disposed over the first metal oxide layer;
an outer surface of the first metal oxide layer facing the first oxygen reservoir layer comprising nitrogen; and
a second metal line coupled to the second electrode and oriented along a second direction over the second electrode; the first electrode, the second electrode, the first oxygen reservoir layer, and the first metal oxide layer, being part of a resistive memory device.

2. The device of claim 1, wherein a portion of the first oxygen reservoir layer comprises a nitrogen profile, wherein a concentration of the nitrogen in the nitrogen profile drops from the outer surface into the first oxygen reservoir layer.

3. The device of claim 1, wherein a portion of the first metal oxide layer comprises a nitrogen profile, and wherein a concentration of the nitrogen in the nitrogen profile drops from the outer surface into the first metal oxide layer.

4. The device of claim 1, wherein the first electrode comprises titanium nitride, tantalum nitride, copper, gold, aluminum, or silver.

5. The device of claim 1, wherein the first metal oxide layer comprises hafnium oxide, zirconium oxide, or hafnium zirconium oxide, and wherein the first oxygen reservoir layer comprises tungsten oxide.

6. The device of claim 1, wherein the first metal oxide layer comprises a thickness between 1 nm and 10 nm.

7. The device of claim 1, further comprising:
a second metal oxide layer disposed over the first oxygen reservoir layer;
a second oxygen reservoir layer disposed over the second metal oxide layer; and
an outer surface of the second metal oxide layer facing the second oxygen reservoir layer comprising nitrogen.

8. The device of claim 1, further comprising:
a transistor coupled to the first electrode, the transistor and the resistive memory device being part of a 1T-1R memory cell.

9. A method of forming a resistive memory, the method comprising:
forming a first metal line disposed over a substrate, the first metal line oriented along a first direction;
forming a patterned stack comprising a first electrode disposed over the first metal line, a first metal oxide layer disposed over the first electrode;
exposing the first metal oxide layer to a nitriding surface treatment process;
forming a first oxygen reservoir layer over the first metal oxide layer;
forming a second electrode over the first oxygen reservoir layer; and
forming a second metal line over the second electrode and oriented along a second direction, wherein the second direction is orthogonal to the first direction.

10. The method of claim 9, wherein exposing to the nitriding surface treatment process comprises:
flowing a nitrogen-containing gas into a process chamber;
powering an electrode of the process chamber to generate a nitrogen-based plasma; and
exposing the substrate to the nitrogen-based plasma.

11. The method of claim 10, wherein nitrogen-containing gas comprises argon, hydrogen, nitrogen, ammonia, hydrazine, or nitrous oxide.

12. The method of claim 9, wherein forming the first metal oxide layer comprises performing a plurality of cycles of deposition, one of the plurality of cycles of deposition comprising:
flowing a first precursor gas for a first time duration into a process chamber, the first precursor gas comprising a metal-containing gas;
exposing the substrate to the metal-containing gas;
purging the process chamber;
flowing a second precursor gas for a second time duration into the process chamber, the second precursor gas comprising a nitrogen-containing gas;
powering an electrode of the process chamber to generate a nitrogen-based plasma;
exposing the substrate to the nitrogen-based plasma; and
purging the process chamber.

13. The method of claim 12, wherein nitrogen-containing gas comprises nitrogen, ammonia, hydrazine, nitrous oxide, oxygen, water vapor, or ozone, and wherein the metal-containing gas comprises tetrakis(dimethylamino)hafnium (TDMAH), tetrakis(ethylmethylamino)hafnium (TEMAH), tetrakis(diethylamido)hafnium (TDEAH), tris(dimethylamino)cyclopentadienyl hafnium (CpHf(NMe₂)₃), tetrakis(dimethylamido)zirconium (TDMAZ), tetrakis(ethylmethylamido)zirconium (TEMAZ), tetrakis(diethylamido)zirconium (TDEAZ), tris(dimethylamino)cyclopentadienyl zirconium (CpZr(NMe₂)₃), tungsten hexafluoride (WF₆), tungsten hexacarbonyl (W(CO)₆), bis(tert-butylimido)bis(N, N′-diisopropylacetamidinato)tungsten (W(N^{t}Bu)₂(ⁱPrAMD)₂), bis(tert-butylimido)-bis(dimethylamido)tungsten (W(N^{t}Bu)₂(NMe₂)₂), bis(cyclopentadienyl)tungsten dihydride (WH₂(Cp)₂), bis(isopropylcyclopentadienyl)tungsten dihydride (WH₂(ⁱPrCp)₂) or hexakis(dimethylamido)ditungsten (W₂(NMe₂)₆).

14. The method of claim 9, wherein the first metal oxide layer comprises hafnium oxide, zirconium oxide, or hafnium zirconium oxide, and wherein the first oxygen reservoir layer comprises tungsten oxide.

15. The method of claim 9, further comprising:
forming a second metal oxide layer between the first electrode and the second electrode, the second metal oxide layer being disposed over the first oxygen reservoir layer;
exposing the second metal oxide layer to a nitriding surface treatment process; and
forming a second oxygen reservoir layer disposed over the second metal oxide layer.

16. The method of claim 9, further comprising:
forming a transistor coupled to the first electrode, the transistor and the resistive memory device being part of a 1T-1R memory cell.

17. A method of forming a resistive memory, the method comprising:
forming a first metal line disposed over a substrate, the first metal line oriented along a first direction;
forming a patterned stack comprising a first electrode disposed over the first metal line;
forming a first oxygen reservoir layer disposed over the first electrode;
exposing the first oxygen reservoir layer to a nitriding surface treatment process;
forming a first metal oxide layer over the first oxygen reservoir layer;
forming a second electrode over the first metal oxide layer; and
forming a second metal line over the second electrode and oriented along a second direction, wherein the second direction is orthogonal to the first direction.

18. The method of claim 17, wherein exposing to the nitriding surface treatment process comprises:
flowing a nitrogen-containing gas into a process chamber;
powering an electrode of the process chamber to generate a nitrogen-based plasma; and
exposing the substrate to the nitrogen-based plasma.

19. The method of claim 18, wherein nitrogen-containing gas comprises argon, hydrogen, nitrogen, ammonia, hydrazine, or nitrous oxide.

20. The method of claim 17, wherein forming the first metal oxide layer comprises performing a plurality of cycles of deposition, one of the plurality of cycles of deposition comprises:
flowing a first precursor gas for a first time duration into a process chamber, the first precursor gas comprising a metal-containing gas;
exposing the substrate to the metal-containing gas;
purging the process chamber;
flowing a second precursor gas for a second time duration into the process chamber, the second precursor gas comprising a nitrogen-containing gas;
powering an electrode of the process chamber to generate a nitrogen-based plasma;
exposing the substrate to the nitrogen-based plasma; and
purging the process chamber.

21. The method of claim 20, wherein nitrogen-containing gas comprises nitrogen, ammonia, hydrazine, nitrous oxide, oxygen, water vapor, or ozone, and wherein the metal-containing gas comprises tetrakis(dimethylamino)hafnium (TDMAH), tetrakis(ethylmethylamino)hafnium (TEMAH), tetrakis(diethylamido)hafnium (TDEAH), tris(dimethylamino)cyclopentadienyl hafnium (CpHf(NMe₂)₃), tetrakis(dimethylamido)zirconium (TDMAZ), tetrakis(ethylmethylamido)zirconium (TEMAZ), tetrakis(diethylamido)zirconium (TDEAZ), tris(dimethylamino)cyclopentadienyl zirconium (CpZr(NMe₂)₃), tungsten hexafluoride (WF₆). tungsten hexacarbonyl (W(CO)₆), bis(tert-butylimido)bis(N, N′-diisopropylacetamidinato)tungsten (W(N^{t}Bu)₂(ⁱPrAMD)₂), bis(tert-butylimido)-bis(dimethylamido)tungsten (W(N^{t}Bu)₂(NMe₂)₂), bis(cyclopentadienyl)tungsten dihydride (WH₂(Cp)₂), bis(isopropylcyclopentadienyl)tungsten dihydride (WH₂(ⁱPrCp)₂) or hexakis(dimethylamido)ditungsten (W₂(NMe₂)₆).

22. The method of claim 17, wherein the first metal oxide layer comprises hafnium oxide, zirconium oxide, or hafnium zirconium oxide, and wherein the first oxygen reservoir layer comprises tungsten oxide.

23. The method of claim 17, further comprising:
forming a second oxygen reservoir layer between the first electrode and the second electrode, the second oxygen reservoir layer being disposed over the first metal oxide layer;
exposing the second oxygen reservoir layer to a nitriding surface treatment process; and
forming a second metal oxide layer disposed over the second oxygen reservoir layer.

24. The method of claim 17, further comprising:
forming a transistor coupled to the first electrode, the transistor and the resistive memory device being part of a 1T-1R memory cell.
